(19) United States
(12) Patent Application Publication
(10) Pub. No.: US 2006/0273299 A1
(43) Pub. Date: Dec. 7, 2006

(54) METHOD FOR MAKING A SEMICONDUCTOR DEVICE INCLUDING A DOPANT BLOCKING SUPERLATTICE

(75) Inventors: Robert John Stephenson, Newton Upper Falls, MA (US); Marek Hytha, Brookline, MA (US)

Correspondence Address: ALLEN, DYER, DOPPELT, MILBRATH & GILCHRIST P.A., 1401 CITRUS CENTER 255 SOUTH ORANGE AVENUE, P.O. BOX 3791, ORLANDO, FL, 32802-3791, US

(73) Assignee: RJ Mears, LLC, Waltham, MA (US)

(21) Appl. No.: 11/380,992

(22) Filed: May 1, 2006

Related U.S. Application Data
(63) Continuation-in-part of application No. 10/992,422, filed on Nov. 18, 2004, now Pat. No. 7,071,119.
Application No. 10/992,422 is a continuation of application No. 10/647,060, filed on Aug. 22, 2003, now Pat. No. 6,958,486.
Application No. 10/647,060 is a continuation-in-part of application No. 10/603,696, filed on Jun. 26, 2003, now abandoned.
Application No. 10/647,060 is a continuation-in-part of application No. 10/603,621, filed on Jun. 26, 2003, now abandoned.

(51) Int. Cl. H01L 29/06

(52) U.S. Cl. 257/15

(57) ABSTRACT

A method for making a semiconductor device may include forming at least one metal oxide field-effect transistor (MOSFET) by forming a body, forming a dopant blocking superlattice adjacent the body, and forming a channel layer adjacent the dopant blocking superlattice and opposite the body. The dopant blocking superlattice may include a plurality of stacked groups of layers. Each group of layers of the dopant blocking superlattice may include a plurality of stacked base semiconductor monolayers defining a base semiconductor portion and at least one non-semiconductor monolayer constrained within a crystal lattice of adjacent base semiconductor portions.

### CROSS-REFERENCE TO RELATED APPLICATIONS

This application is a continuation-in-part of U.S. patent application Ser. No. 10/992,422 filed Nov. 18, 2004, which is a continuation of U.S. patent application Ser. No. 10/647,060 filed Aug. 22, 2003, which is a continuation-in-part of U.S. patent application Ser. Nos. 10/603,696 and 10/603,621 filed on Jun. 26, 2003, the entire disclosures of which are incorporated by reference herein.

### FIELD OF THE INVENTION

The present invention relates to the field of semiconductors, and, more particularly, to semiconductors having enhanced properties such as based upon energy band engineering and associated methods.

### BACKGROUND OF THE INVENTION

Structures and techniques have been proposed to enhance the performance of semiconductor devices, such as by enhancing the mobility of the charge carriers. For example, U.S. Patent Application No. 2003/0057416 to Currie et al. discloses strained material layers of silicon, silicon-germanium, and relaxed silicon and also including impurity-free zones that would otherwise cause performance degradation. The resulting biaxial strain in the upper silicon layer alters the carrier mobilities enabling higher speed and/or lower power devices. Published U.S. Patent Application No. 2003/0034529 to Fitzgerald et al. discloses a CMOS inverter also based upon similar strained silicon technology.

U.S. Pat. No. 6,472,685 B2 to Takagi discloses a semiconductor device including a silicon and carbon layer sandwiched between silicon layers so that the conduction band and valence band of the second silicon layer receive a tensile strain. Electrons having a smaller effective mass, and which have been induced by an electric field applied to the gate electrode, are confined in the second silicon layer, thus, an n-channel MOSFET is asserted to have a higher mobility.

U.S. Pat. No. 4,937,204 to Ishibashi et al. discloses a superlattice in which a plurality of layers, less than eight monolayers, and containing a fraction or a binary compound semiconductor layers, are alternately and epitaxially grown. The direction of main current flow is perpendicular to the layers of the superlattice.

U.S. Pat. No. 5,357,119 to Wang et al. discloses a Si—Ge short period superlattice with higher mobility achieved by reducing alloy scattering in the superlattice. Along these lines, U.S. Pat. No. 5,683,934 to Candelaria discloses an enhanced mobility MOSFET including a channel layer comprising an alloy of silicon and a second material substitutionally present in the silicon lattice at a percentage that places the channel layer under tensile stress.

U.S. Pat. No. 5,216,262 to Tsu discloses a quantum well structure comprising two barrier regions and a thin epitaxially grown semiconductor layer sandwiched between the barriers. Each barrier region consists of alternate layers of SiO₂/Si with a thickness generally in a range of two to six monolayers. A much thicker section of silicon is sandwiched between the barriers.

An article entitled “Phenomena in silicon nanostructure devices” also to Tsu and published online Sep. 6, 2000 by Applied Physics and Materials Science & Processing, pp. 391-402 discloses a semiconductor-atomic superlattice (SAS) of silicon and oxygen. The Si/O superlattice is disclosed as useful in a silicon quantum and light-emitting devices. In particular, a green electromuminescence diode structure was constructed and tested. Current flow in the diode structure is vertical, that is, perpendicular to the layers of the SAS. The disclosed SAS may include semiconductor layers separated by adsorbed species such as oxygen atoms, and CO molecules. The silicon growth beyond the adsorbed monolayer of oxygen is described as epitaxial with a fairly low defect density. One SAS structure included a 1.1 nm thick silicon portion that is about eight atomic layers of silicon, and another structure had twice this thickness of silicon. An article to Luo et al. entitled “Chemical Design of Direct-Gap Light-Emitting Silicon” published in Physical Review Letters, Vol. 89, No. 7 (Aug. 12, 2002) further discusses the light emitting SAS structures of Tsu.

Published International Application WO 02/103,767 A1 to Wang, Tsu and Lofgren, discloses a barrier building block of thin silicon and oxygen, carbon, nitrogen, phosphorous, antimony, arsenic or hydrogen to thereby reduce current flowing vertically through the lattice more than four orders of magnitude. The insulating layer/barrier layer allows for low defect epitaxial silicon to be deposited next to the insulating layer.

Published Great Britain Patent Application 2,347,520 to Mears et al. discloses that principles of Aperiodic Photonic Band-Gap (APBG) structures may be adapted for electronic bandgap engineering. In particular, the application discloses that material parameters, for example, the location of band minima, effective mass, etc, can be tailored to yield new aperiodic materials with desirable band-structure characteristics. Other parameters, such as electrical conductivity, thermal conductivity and dielectric permittivity or magnetic permeability are disclosed as also possible to be designed into the material.

Despite considerable efforts at materials engineering to increase the mobility of charge carriers in semiconductor devices, there is still a need for greater improvements. Greater mobility may increase device speed and/or reduce device power consumption. With greater mobility, device performance can also be maintained despite the continued shift to smaller device features. Moreover, as device sizes decrease regions within devices become closer together and dopant diffusion between regions can become problematic. For example, in MOSFET devices dopant from body implants, etc. may diffuse into the channel of the device and degrade device performance.

### SUMMARY OF THE INVENTION

In view of the foregoing background, it is therefore an object of the present invention to provide a method for making a semiconductor device with a dopant blocking layer to reduce channel degradation caused by dopant diffusion, for example.

This and other objects, features, and advantages in accordance with the present invention are provided by a method for making a semiconductor device which may include forming at least one metal oxide field-effect transistor (MOSFET) by forming a body, forming a dopant blocking superlattice adjacent the body, and forming a channel layer adjacent the dopant blocking superlattice and opposite the body. More particularly, the dopant blocking superlattice may include a plurality of stacked groups of layers. Each group of layers of the dopant blocking superlattice may include a plurality of stacked base semiconductor monolayers defining a base semiconductor portion and at least one non-semiconductor monolayer constrained within a crystal lattice of adjacent base semiconductor portions.

Because of the layered structure of the superlattice and the constrained non-semiconductor monolayer(s), the superlattice advantageously blocks unwanted diffusion of dopants between the body and the channel layer. Moreover, the dopant blocking superlattice may have a relatively small thickness. In addition, the superlattice also enjoys enhanced mobility properties which may also be utilized in certain applications in addition to its dopant blocking ability, such as if a portion of the MOSFET channel is formed in the dopant blocking superlattice.

Additionally, the body may have at least one doped region therein. By way of example, the body may have a dopant concentration of greater than about 1×10⁸ cm⁻³. Furthermore, the channel layer may be substantially undoped, i.e., having a dopant concentration of less than about 1×10⁵ cm⁻³, for example. At least one group of layers of the dopant blocking superlattice may also be substantially undoped.

The base semiconductor may comprise silicon, and the at least one non-semiconductor monolayer may comprise oxygen, for example. In particular, the at least one non-semiconductor monolayer may comprise a non-semiconductor selected from the group consisting essentially of oxygen, nitrogen, fluorine, and carbon-oxygen.

The method may further include forming a gate overlying the channel layer by forming a gate insulating layer adjacent the channel layer, and a gate electrode adjacent the gate insulating layer and opposite the channel layer. Source and drain regions may also be formed laterally adjacent the channel layer.

The at least one non-semiconductor monolayer may be a single monolayer thick, and the base semiconductor portion may be less than eight monolayers thick. All of the base semiconductor portions may be a same number of monolayers thick. Alternately, at least some of the base semiconductor portions may be a different number of monolayers thick. Also, opposing base semiconductor monolayers in adjacent groups of layers of the superlattice may be chemically bound together.

### BRIEF DESCRIPTION OF THE DRAWINGS

FIG. 1 is schematic cross-sectional diagram of a semiconductor device in accordance with the present invention including a dopant blocking superlattice.

FIG. 2 is a greatly enlarged schematic cross-sectional view of the superlattice as shown in FIG. 1.

FIG. 3 is a perspective schematic atomic diagram of a portion of the superlattice shown in FIG. 1.

FIG. 4 is a greatly enlarged schematic cross-sectional view of another embodiment of a superlattice that may be used in the device of FIG. 1.

FIG. 5A is a graph of the calculated band structure from the gamma point (G) for both bulk silicon as in the prior art, and for the 4/1 Si/O superlattice as shown in FIGS. 1-3.

FIG. 5B is a graph of the calculated band structure from the Z point for both bulk silicon as in the prior art, and for the 4/1 Si/O superlattice as shown in FIGS. 1-3.

FIG. 5C is a graph of the calculated band structure from both the gamma and Z points for both bulk silicon as in the prior art, and for the 5/1/3/1 Si/O superlattice as shown in FIG. 4.

FIGS. 6A-6D are a series of schematic cross-sectional diagrams illustrating a method for making the semiconductor device of FIG. 1.

### DETAILED DESCRIPTION OF THE PREFERRED EMBODIMENTS

The present invention will now be described more fully hereinafter with reference to the accompanying drawings, in which preferred embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like numbers refer to like elements throughout, and prime notation is used to indicate similar elements in alternate embodiments.

The present invention relates to controlling the properties of semiconductor materials at the atomic or molecular level to achieve improved performance within semiconductor devices. Further, the invention relates to the identification, creation, and use of improved materials for use in the conduction paths of semiconductor devices.

Applicants theorize, without wishing to be bound thereto, that certain superlattices as described herein reduce the effective mass of charge carriers and that this thereby leads to higher charge carrier mobility. Effective mass is described with various definitions in the literature. As a measure of the improvement in effective mass Applicants use a “conductivity reciprocal effective mass tensor”, Mₑ⁻¹ and Mₕ⁻¹ for electrons and holes respectively, defined as:

$${M}_{e , ij}^{- 1} ( {E}_{F} , T ) = \frac{{\sum }_{E > {E}_{F}} {\int }_{B . Z .}^{} {( {∇}_{k} E ( k , n ) )}_{i} {( {∇}_{k} E ( k , n ) )}_{j} \frac{\partial f ( E ( k , n ) , {E}_{F} , T )}{\partial E} {ⅆ}^{3} k}{{\sum }_{E > {E}_{F}} {\int }_{B . Z .}^{} f ( E ( k , n ) , {E}_{F} , T ) {ⅆ}^{3} k}$$

for electrons and:

$${M}_{h , ij}^{- 1} ( {E}_{F} , T ) = \frac{- {\sum }_{E < {E}_{F}} {\int }_{B . Z .}^{} {( {∇}_{k} E ( k , n ) )}_{i} {( {∇}_{k} E ( k , n ) )}_{j} \frac{\partial f ( E ( k , n ) , {E}_{F} , T )}{\partial E} {ⅆ}^{3} k}{{\sum }_{E < {E}_{F}} {\int }_{B . Z .}^{} ( 1 - f ( E ( k , n ) , {E}_{F} , T ) ) {ⅆ}^{3} k}$$

for holes, where f is the Fermi-Dirac distribution, E_{F} is the Fermi energy, T is the temperature, E(k,n) is the energy of an electron in the state corresponding to wave vector k and the n^{th} energy band, the indices i and j refer to Cartesian coordinates x, y and z, the integrals are taken over the Brillouin zone (B.Z.), and the summations are taken over bands with energies above and below the Fermi energy for electrons and holes respectively.

Applicants' definition of the conductivity reciprocal effective mass tensor is such that a tensorial component of the conductivity of the material is greater for greater values of the corresponding component of the conductivity reciprocal effective mass tensor. Again Applicants theorize without wishing to be bound thereto that the superlattices described herein set the values of the conductivity reciprocal effective mass tensor so as to enhance the conductive properties of the material, such as typically for a preferred direction of charge carrier transport. The inverse of the appropriate tensor element is referred to as the conductivity effective mass. In other words, to characterize semiconductor material structures, the conductivity effective mass for electrons/holes as described above and calculated in the direction of intended carrier transport is used to distinguish improved materials.

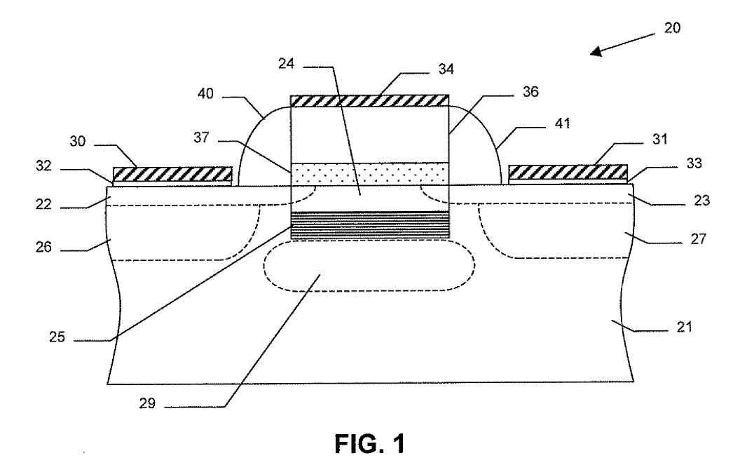

Using the above-described measures, one can select materials having improved band structures for specific purposes. One such example would be a superlattice 25 material used as a dopant blocking layer in a semiconductor device. A planar MOSFET 20 including the superlattice 25 in accordance with the invention is first described with reference to FIG. 1. One skilled in the art, however, will appreciate that the materials identified herein could be used in many different types of semiconductor devices, such as discrete devices and/or integrated circuits. By way of example, another application in which the superlattice 25 may be used as a dielectric interface layers is FINFETs.

The illustrated MOSFET 20 includes a substrate 21 with one or more body implants 29 therein. Lightly doped source/drain extension regions 22, 23 and more heavily doped source/drain regions 26, 27 are also implanted in the substrate 21. A channel layer 24 illustratively extends between the lightly doped source/drain extension regions 22, 23. The superlattice 25 is advantageously positioned between the body implant 29 and the channel layer 24 as a dopant blocking layer to block diffusion of dopant into the channel.

More particularly, one or more body implants 29 may be used for setting a voltage threshold (V_{T}) of the MOSFET 20, and/or for reducing punch through effect, as will be appreciated by those skilled in the art. By way of example, such body implants may have a dopant concentration of greater than about 1×10¹⁸ cm⁻³. Yet, in many applications it is desirable to have a substantially undoped channel. By “substantially undoped,” it is meant that no dopants are intentionally added, although it will be appreciated by those skilled in the art that impurities may still be present from semiconductor processing. As such, the dopant concentration in the substantially undoped channel layer 24 may preferably be less than about 1×10¹⁵ cm⁻³, and, more preferably, less than about 5×10¹⁴ cm⁻³, for example.

In typical prior art MOSFET devices in which the channel directly overlies the body implant, it may be difficult to prevent dopant diffusion into the channel. Because of its structure, the superlattice 25 advantageously blocks unwanted diffusion of dopants between the body and the channel layer 24, as will be discussed further below.

A gate dielectric layer 37 (which is shown with stippling for clarity of illustration in FIG. 1) is on the channel layer 24, and a gate electrode layer 36 is on the gate dielectric layer and opposite the channel layer. Sidewall spacers 40, 41 are also provided in the illustrated MOSFET 20, as well as silicide layers 30, 31 and respective source/drain contacts 32, 33 on the lightly doped source and drain regions 22, 23. A silicide layer 34 is also on the gate electrode layer 36.

Applicants have identified improved materials or structures for the superlattice 25 of the MOSFET 20. More specifically, the Applicants have identified materials or structures having energy band structures for which the appropriate conductivity effective masses for electrons and/or holes are substantially less than the corresponding values for silicon.

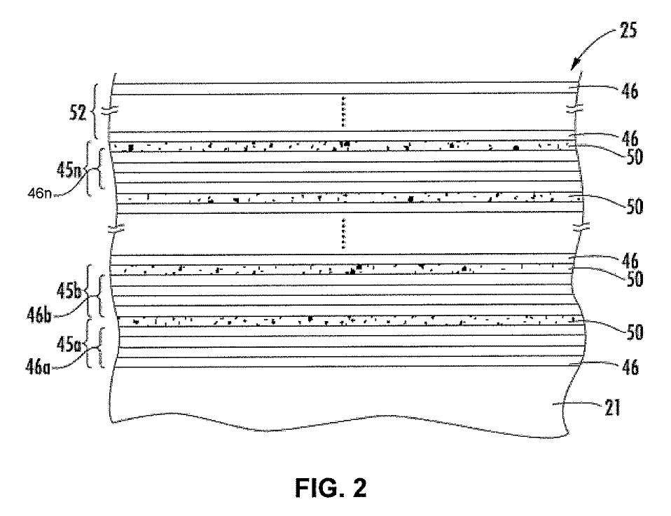

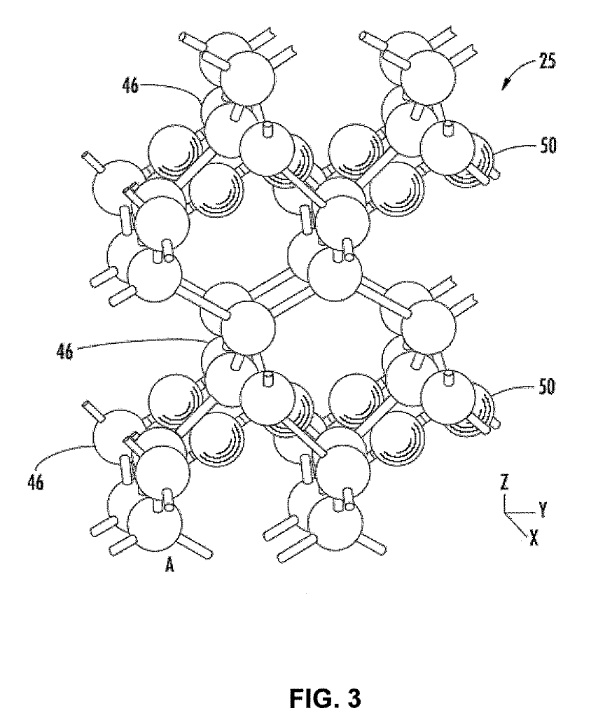

Referring now additionally to FIGS. 2 and 3, the materials or structures are in the form of a superlattice 25 whose structure is controlled at the atomic or molecular level and may be formed using known techniques of atomic or molecular layer deposition. The superlattice 25 includes a plurality of layer groups 45a-45n arranged in stacked relation, as perhaps best understood with specific reference to the schematic cross-sectional view of FIG. 2.

Each group of layers 45a-45n of the superlattice 25 illustratively includes a plurality of stacked base semiconductor monolayers 46 defining a respective base semiconductor portion 46a-46n and an energy band-modifying layer 50 thereon. The energy band-modifying layers 50 are indicated by stippling in FIG. 2 for clarity of illustration.

The energy-band modifying layer 50 illustratively includes one non-semiconductor monolayer constrained within a crystal lattice of adjacent base semiconductor portions. That is, opposing base semiconductor monolayers 46 in adjacent groups of layers 45a-45n are chemically bound together. For example, in the case of silicon monolayers 46, some of the silicon atoms in the upper or top semiconductor monolayer of the group of monolayers 46a will be covalently bonded with silicon atoms in the lower or bottom monolayer of the group 46b. This allows the crystal lattice to continue through the groups of layers despite the presence of the non-semiconductor monolayer(s) (e.g., oxygen monolayer(s)). Of course, there will not be a complete or pure covalent bond between the opposing silicon layers 46 of adjacent groups 45a-45n as some of the silicon atoms in each of these layers will be bonded to non-semiconductor atoms (i.e., oxygen in the present example), as will be appreciated by those skilled in the art.

In other embodiments, more than one non-semiconductor layer monolayer may be possible. By way of example, the number of non-semiconductor monolayers in the energy band-modifying layer 50 may preferably be less than about five monolayers to thereby provide desired energy band-modifying properties.

It should be noted that reference herein to a non-semiconductor or semiconductor monolayer means that the material used for the monolayer would be a non-semiconductor or semiconductor if formed in bulk. That is, a single monolayer of a material, such as semiconductor, may not necessarily exhibit the same properties that it would if formed in bulk or in a relatively thick layer, as will be appreciated by those skilled in the art.

Applicants theorize without wishing to be bound thereto that energy band-modifying layers 50 and adjacent base semiconductor portions 46a-46n cause the superlattice 25 to have a lower appropriate conductivity effective mass for the charge carriers in the parallel layer direction than would otherwise be present. Considered another way, this parallel direction is orthogonal to the stacking direction. The band modifying layers 50 may also cause the superlattice 25 to have a common energy band structure, while also advantageously functioning as an insulator between layers or regions vertically above and below the superlattice. Moreover, as noted above, this structure also advantageously provides a barrier to dopant and/or material bleed or diffusion between layers vertically above and below the superlattice 25.

It is also theorized that a semiconductor device, such as the illustrated MOSFET 20, will enjoy a higher charge carrier mobility based upon the lower conductivity effective mass than would otherwise be present. In some embodiments, and as a result of the band engineering achieved by the present invention, the superlattice 25 may further have a substantially direct energy bandgap that may be particularly advantageous for opto-electronic devices, for example, as described in further detail below. Of course, all of the above-described properties of the superlattice 25 need not be utilized in every application. For example, in some applications the superlattice 25 may only be used for its dopant blocking/insulation properties or its enhanced mobility, or it may be used for both in other applications, as will be appreciated by those skilled in the art.

Moreover, because of the above-described lower appropriate conductivity effective mass for the charge carriers in the parallel layer direction, in some embodiments the superlattice 25 may also advantageously be used to provide the channel layer 24. More particularly, in the illustrated embodiment the channel layer 24 of the MOSFET 20 is a cap layer 52 of the superlattice 25. Yet, in some embodiments the superlattice 25 may be made sufficiently thick so that portions of the channel are defined in the upper group(s) of layers 45 of the superlattice. In other embodiments, a second channel superlattice layer may be grown on the dopant blocking superlattice 25, for example. Further details on using such a superlattice as a channel in a semiconductor device are provided in U.S. application Ser. No. 10/647,069, which is assigned to the present Assignee and is hereby incorporated in its entirety by reference, for example.

The cap layer 52 is on an upper layer group 45n of the superlattice 25. The cap layer 52 may comprise a plurality of base semiconductor monolayers 46. The cap layer 52 may have between 2 to 100 monolayers of the base semiconductor, and, more preferably between 10 to 50 monolayers. Other thicknesses may be used as well.

Each base semiconductor portion 46a-46n may comprise a base semiconductor selected from the group consisting of Group IV semiconductors, Group III-V semiconductors, and Group II-VI semiconductors. Of course, the term Group IV semiconductors also includes Group IV-IV semiconductors, as will be appreciated by those skilled in the art. More particularly, the base semiconductor may comprise at least one of silicon and germanium, for example.

Each energy band-modifying layer 50 may comprise a non-semiconductor selected from the group consisting of oxygen, nitrogen, fluorine, and carbon-oxygen, for example. The non-semiconductor is also desirably thermally stable through deposition of a next layer to thereby facilitate manufacturing. In other embodiments, the non-semiconductor may be another inorganic or organic element or compound that is compatible with the given semiconductor processing, as will be appreciated by those skilled in the art.

It should be noted that the term “monolayer” is meant to include a single atomic layer and also a single molecular layer. It is also noted that the energy band-modifying layer 50 provided by a single monolayer is also meant to include a monolayer wherein not all of the possible sites are occupied. For example, with particular reference to the atomic diagram of FIG. 3, a 4/1 repeating structure is illustrated for silicon as the base semiconductor material, and oxygen as the energy band-modifying material. Only half of the possible sites for oxygen are occupied.

In other embodiments and/or with different materials this one half occupation would not necessarily be the case as will be appreciated by those skilled in the art. Indeed it can be seen even in this schematic diagram, that individual atoms of oxygen in a given monolayer are not precisely aligned along a flat plane as will also be appreciated by those of skill in the art of atomic deposition. By way of example, a preferred occupation range is from about one-eighth to one-half of the possible oxygen sites being full, although other numbers may be used in certain embodiments.

Silicon and oxygen are currently widely used in conventional semiconductor processing, and, hence, manufacturers will be readily able to use these materials as described herein. Atomic or monolayer deposition is also now widely used. Accordingly, semiconductor devices incorporating the superlattice 25 in accordance with the invention may be readily adopted and implemented, as will be appreciated by those skilled in the art.

It is theorized without Applicants wishing to be bound thereto, that for a superlattice, such as the Si/O superlattice, for example, that the number of silicon monolayers should desirably be seven or less so that the energy band of the superlattice is common or relatively uniform throughout to achieve the desired advantages. The 4/1 repeating structure shown in FIGS. 2 and 3, for Si/O has been modeled to indicate an enhanced mobility for electrons and holes in the X direction. For example, the calculated conductivity effective mass for electrons (isotropic for bulk silicon) is 0.26 and for the 4/1 SiO superlattice in the X direction it is 0.12 resulting in a ratio of 0.46, Similarly, the calculation for holes yields values of 0.36 for bulk silicon and 0.16 for the 4/1 Si/O superlattice resulting in a ratio of 0.44.

While such a directionally preferential feature may be desired in certain semiconductor devices, other devices may benefit from a more uniform increase in mobility in any direction parallel to the groups of layers. It may also be beneficial to have an increased mobility for both electrons and holes, or just one of these types of charge carriers, as will be appreciated by those skilled in the art.

The lower conductivity effective mass for the 4/1 Si/C embodiment of the superlattice 25 may be less than two-thirds the conductivity effective mass than would otherwise occur, and this applies for both electrons and holes. Of course, the superlattice 25 may further comprise at least one type of conductivity dopant therein, as will also be appreciated by those skilled in the art. It may be especially appropriate to dope some portion of the superlattice 25 if the superlattice is to provide a portion of the channel, for example. In other embodiments, it may be preferably to have one or more groups of layers 45 of the superlattice 25 substantially undoped.

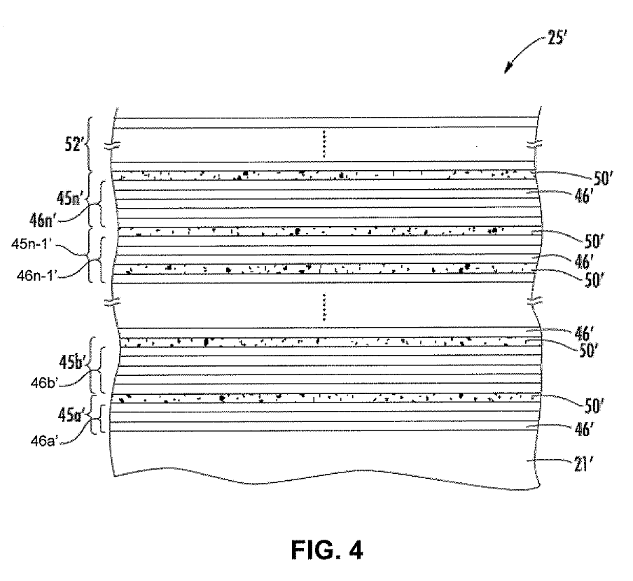

Referring now additionally to FIG. 4, another embodiment of a superlattice 25′ in accordance with the invention having different properties is now described. In this embodiment, a repeating pattern of 3/1/5/1 is illustrated. More particularly, the lowest base semiconductor portion 46a′ has three monolayers, and the second lowest base semiconductor portion 46b′ has five monolayers. This pattern repeats throughout the superlattice 25′. The energy band-modifying layers 50′ may each include a single monolayer. For such a superlattice 25′ including Si/O, the enhancement of charge carrier mobility is independent of orientation in the plane of the layers. Those other elements of FIG. 4 not specifically mentioned are similar to those discussed above with reference to FIG. 2 and need no further discussion herein.

In some device embodiments, all of the base semiconductor portions 46a-46n of a superlattice 25 may be a same number of monolayers thick. In other embodiments, at least some of the base semiconductor portions 46a-46n may be a different number of monolayers thick. In still other embodiments, all of the base semiconductor portions 46a-46n may be a different number of monolayers thick.

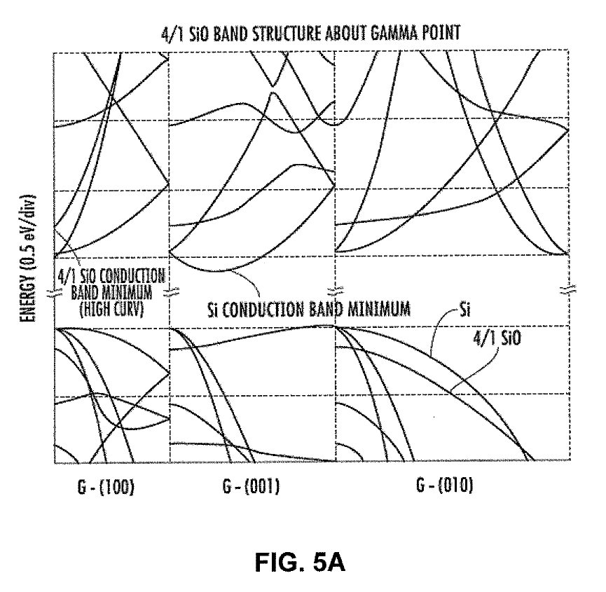

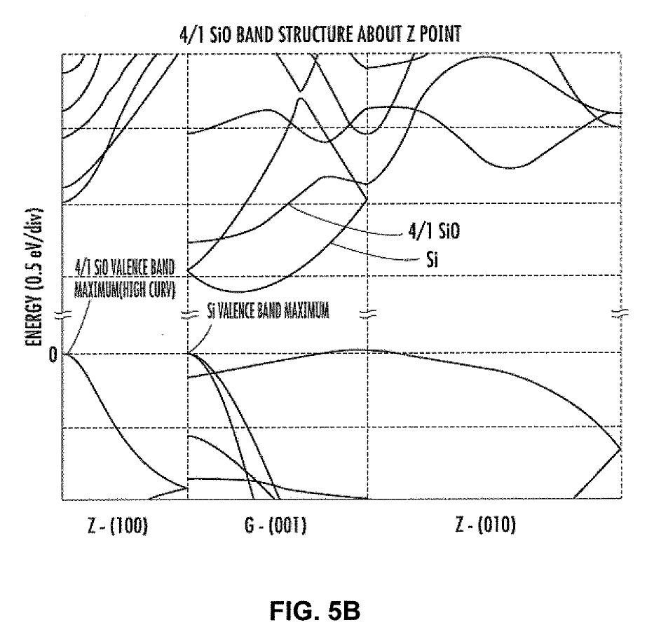

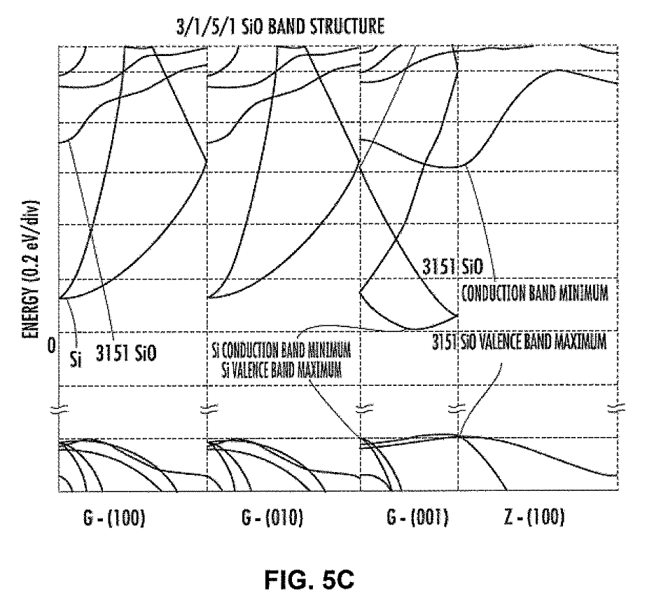

In FIGS. 5A-5C band structures calculated using Density Functional Theory (DFT) are presented. It is well known in the art that DFT underestimates the absolute value of the bandgap. Hence all bands above the gap may be shifted by an appropriate “scissors correction.” However the shape of the band is known to be much more reliable. The vertical energy axes should be interpreted in this light.

FIG. 5A shows the calculated band structure from the gamma point (G) for both bulk silicon (represented by continuous lines) and for the 4/1 Si/O superlattice 25 as shown in FIGS. 1-3 (represented by dotted lines). The directions refer to the unit cell of the 4/1 Si/O structure and not to the conventional unit cell of Si, although the (001) direction in the figure does correspond to the (001) direction of the conventional unit cell of Si, and, hence, shows the expected location of the Si conduction band minimum. The (100) and (010) directions in the figure correspond to the (110) and (−110) directions of the conventional Si unit cell. Those skilled in the art will appreciate that the bands of Si on the figure are folded to represent them on the appropriate reciprocal lattice directions for the 4/1 Si/O structure.

It can be seen that the conduction band minimum for the 4/1 Si/O structure is located at the gamma point in contrast to bulk silicon (Si), whereas the valence band minimum occurs at the edge of the Brillouin zone in the (001) direction which we refer to as the Z point. One may also note the greater curvature of the conduction band minimum for the 4/1 Si/O structure compared to the curvature of the conduction band minimum for Si owing to the band splitting due to the perturbation introduced by the additional oxygen layer.

FIG. 5B shows the calculated band structure from the Z point for both bulk silicon (continuous lines) and for the 4/1 Si/O superlattice 25 (dotted lines). This figure illustrates the enhanced curvature of the valence band in the (100) direction.

FIG. 5C shows the calculated band structure from both the gamma and Z point for both bulk silicon (continuous lines) and for the 5/1/3/1 Si/C structure of the superlattice 25′ of FIG. 4 (dotted lines). Due to the symmetry of the 5/1/3/1 Si/O structure, the calculated band structures in the (100) and (010) directions are equivalent. Thus the conductivity effective mass and mobility are expected to be isotropic in the plane parallel to the layers, i.e. perpendicular to the (001) stacking direction. Note that in the 5/1/3/1 Si/C example the conduction band minimum and the valence band maximum are both at or close to the Z point.

Although increased curvature is an indication of reduced effective mass, the appropriate comparison and discrimination may be made via the conductivity reciprocal effective mass tensor calculation. This leads Applicants to further theorize that the 5/1/3/1 superlattice 25′ should be substantially direct bandgap. As will be understood by those skilled in the art, the appropriate matrix element for optical transition is another indicator of the distinction between direct and indirect bandgap behavior.

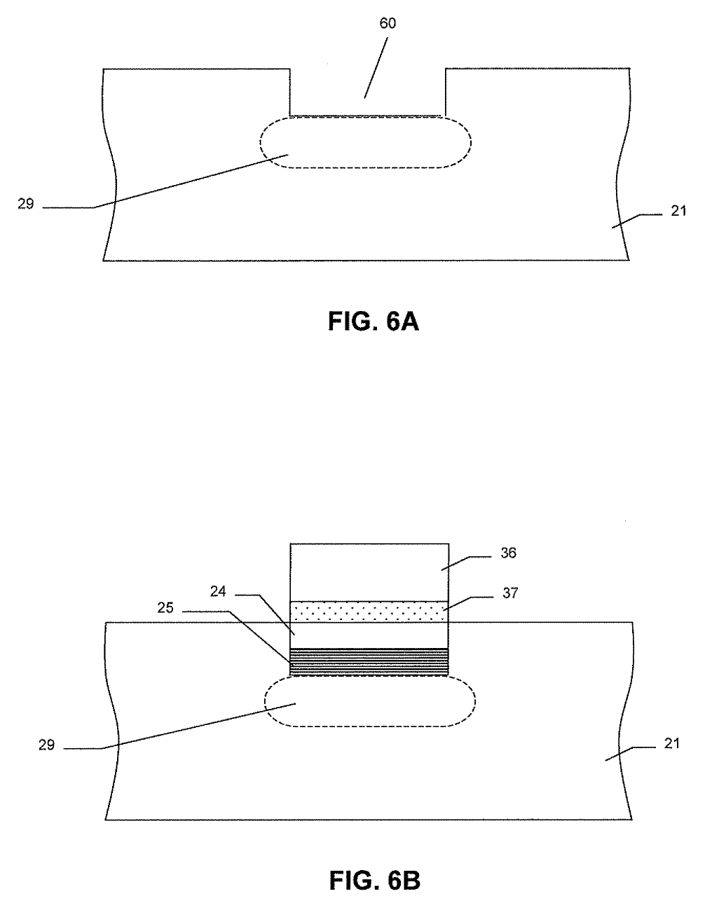

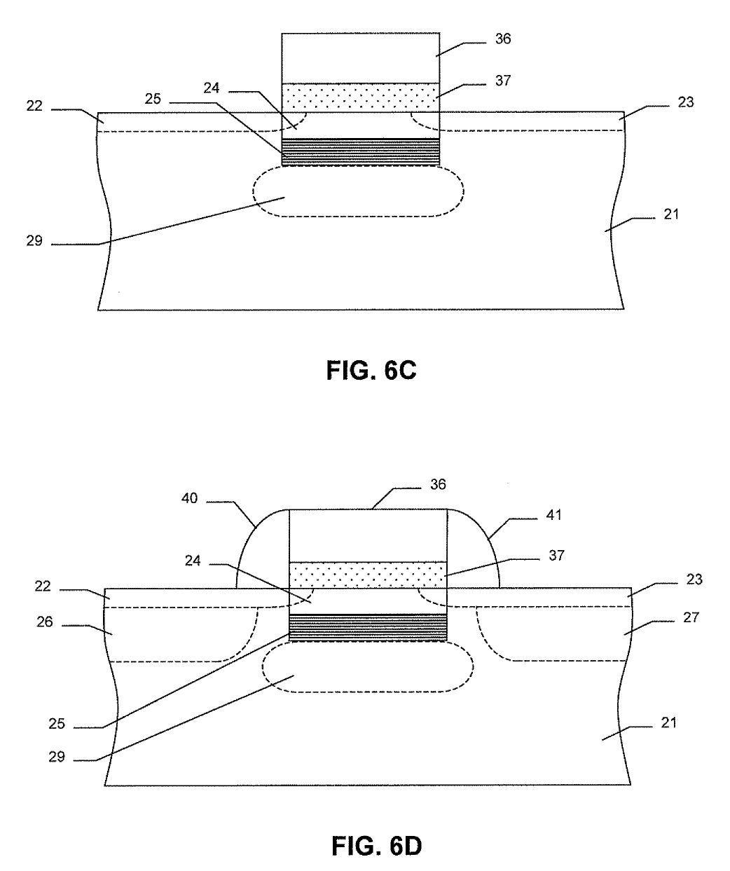

Referring now additionally to FIGS. 6A-GE, a method for making the MOSFET 20 will now be described. The method begins with providing the silicon substrate 21. By way of example, the substrate may be an eight-inch wafer 21 of lightly doped P-type or N-type single crystal silicon with <100> orientation, although other suitable substrates may also be used. In accordance with the present example, a trench 60 is formed in the substrate and the body implant(s) 29 is formed in the trench. Of course, it will be appreciated that in other embodiments the body implants may be performed before the trench 60 is formed.

Next, a layer of the superlattice 25 material is formed in the trench 60. More particularly, the superlattice 25 material is deposited in the trench 60 using atomic layer deposition, and the epitaxial silicon cap layer 52 is formed thereon to provide the channel layer 24 of the MOSFET 20, as discussed previously above, and the surface is planarized.

It should be noted that in some embodiments the superlattice 25 material may be selectively deposited in desired areas, rather than across the entire substrate 21, as will be appreciated by those skilled in the art. That is, the superlattice may be formed on the upper surface of the substrate 21 in some embodiments without a trench 60, and the source/drain regions 22, 26 and 23, 27 may be epitaxially formed laterally adjacent thereto. Moreover, planarization may not be required in all embodiments.

The epitaxial silicon cap layer 52 may have a preferred thickness to prevent channel consumption during gate oxide growth, or any other subsequent oxidations. According to the well-known relationship of consuming approximately 45% of the underlying silicon for a given oxide grown, the silicon cap layer may be sized accordingly as would be known to those skilled in the art.

Once formation of the superlattice 25 is completed, the gate dielectric layer 37 and the gate electrode layer 36 are formed. More particularly, the dielectric material is deposited, and steps of poly deposition, patterning, and etching are performed to provide the gate stack illustrated in FIG. 6B. Poly deposition refers to low-pressure chemical vapor deposition (LPCVD) of silicon onto an oxide (hence it forms a polycrystalline material). The step includes doping with P+ or As− to make it conducting, and the layer may be around 250 nm thick, for example.

In addition, the pattern step may include performing a spinning photoresist, baking, exposure to light (i.e., a photolithography step), and developing the resist. Usually, the pattern is then transferred to another layer (oxide or nitride) which acts as an etch mask during the etch step. The etch step typically is a plasma etch (anisotropic, dry etch) that is material selective (e.g., etches silicon ten times faster than oxide) and transfers the lithography pattern into the material of interest.

While etching of the superlattice 25 is not required in the illustrated embodiment, in those embodiments where the dopant blocking superlattice is formed on the upper surface of the substrate 21 as discussed above, the superlattice 25 material may be etched using known semiconductor processing techniques. However, it should be noted that with the non-semiconductor present in the superlattice 25, e.g., oxygen, the superlattice may be more easily etched using an etchant formulated for oxides rather than silicon. Of course, the appropriate etch for a given implementation will vary based upon the structure and materials used for the superlattice 25 and substrate 21, as will be appreciated by those of skill in the art.

In FIG. 6C, the lightly doped source and drain (“LDD”) extensions 22, 23 are formed. These regions are formed using n-type or p-type LDD implantation, annealing, and cleaning. An anneal step may be used after the LDD implantation, but depending on the specific process, it may be omitted. The clean step is a chemical etch to remove metals and organics prior to depositing an oxide layer.

FIG. 6D shows the formation of the sidewall spacers 40, 41 and the source and drain 26, 27 implants. An SiO₂ mask may be deposited and etched back for this purpose. N-type or p-type ion implantation is used to form the source and drain regions 26, 27, depending upon the given implementation. The structure is then annealed and cleaned. Self-aligned silicide formation may then be performed to form the silicide layers 30, 31, and 34, and the source/drain contacts 32, 33, are formed to provide the final semiconductor device 20 illustrated in FIG. 1. The silicide formation is also known as salicidation. The salicidation process includes metal deposition (e.g., Ti), nitrogen annealing, metal etching, and a second annealing.

The foregoing is, of course, but one example of a process and device in which the present invention may be used, and those of skill in the art will understand its application and use in many other processes and devices. In other processes and devices the structures of the present invention may be formed on a portion of a wafer or across substantially all of a wafer. Additionally, the use of an atomic layer deposition tool may also not be needed for forming the superlattice 25 in some embodiments. For example, the monolayers may be formed using a CVD tool with process conditions compatible with control of monolayers, as will be appreciated by those skilled in the art. Further details regarding fabrication of semiconductor devices in accordance with the present invention may be found in the above-noted U.S. application Ser. No. 10/467,069, for example.

Many modifications and other embodiments of the invention will come to the mind of one skilled in the art having the benefit of the teachings presented in the foregoing descriptions and the associated drawings. Therefore, it is understood that the invention is not to be limited to the specific embodiments disclosed, and that modifications and embodiments are intended to be included within the scope of the appended claims.

That which is claimed is:

1. A method for making a semiconductor device comprising:
forming at least one metal oxide field-effect transistor (MOSFET) by
forming a body,
forming a dopant blocking superlattice adjacent the body comprising a plurality of stacked groups of layers, each group of layers of the dopant blocking superlattice comprising a plurality of stacked base semiconductor monolayers defining a base semiconductor portion and at least one non-semiconductor monolayer constrained within a crystal lattice of adjacent base semiconductor portions, and
forming a channel layer adjacent the dopant blocking superlattice and opposite the body.

2. The method of claim 1 wherein the body has at least one doped region therein.

3. The method of claim 1 wherein the body has a dopant concentration of greater than about 1×10¹⁸ cm⁻³.

4. The method of claim 1 wherein the channel layer is substantially undoped.

5. The method of claim 1 wherein the channel layer has a dopant concentration of less than about 1×10¹⁵ cm⁻³.

6. The method of claim 1 wherein at least one group of layers of the dopant blocking superlattice is substantially undoped.

7. The method of claim 1 wherein the base semiconductor comprises silicon.

8. The method of claim 7 wherein the at least one non-semiconductor monolayer comprises oxygen.

9. The method of claim 1 wherein the at least one non-semiconductor monolayer comprises a non-semiconductor selected from the group consisting essentially of oxygen, nitrogen, fluorine, and carbon-oxygen.

10. The method of claim 1 further comprising forming a gate overlying the channel layer.

11. The method of claim 10 further comprising forming source and drain regions laterally adjacent the channel layer.

12. The method of claim 10 wherein forming the gate comprises forming a gate insulating layer adjacent the semiconductor channel layer, and a gate electrode adjacent the gate insulating layer and opposite the channel layer.

13. The method of claim 1 wherein the at least one non-semiconductor monolayer is a single monolayer thick.

14. The method of claim 1 wherein the base semiconductor portion is less than eight monolayers thick.

15. The method of claim 1 wherein all of the base semiconductor portions are a same number of monolayers thick.

16. The method of claim 1 wherein at least some of the base semiconductor portions are a different number of monolayers thick.

17. The method of claim 1 wherein opposing base semiconductor monolayers in adjacent groups of layers of the superlattice are chemically bound together.

18. A method for making a semiconductor device comprising:
forming at least one metal oxide field-effect transistor (MOSFET) by
forming a body,
forming a dopant blocking superlattice adjacent the body comprising a plurality of stacked groups of layers, each group of layers of the dopant blocking superlattice comprising a plurality of stacked base silicon monolayers defining a base silicon portion and at least one oxygen monolayer constrained within a crystal lattice of adjacent base silicon portions,
forming a channel layer adjacent the dopant blocking superlattice and opposite the body,
forming a gate overlying the channel layer, and
forming source and drain regions laterally adjacent the channel layer.

19. The method of claim 18 wherein the body has at least one doped region therein.

20. The method of claim 18 wherein the body has a dopant concentration of greater than about 1×10¹⁸ cm⁻³.

21. The method of claim 18 wherein the channel layer is substantially undoped.

22. The method of claim 18 wherein the channel layer has a dopant concentration of less than about 1×10¹⁵ cm³.

23. The method of claim 18 wherein at least one group of layers of the dopant blocking superlattice is substantially undoped.
